(19) United States
(12) Patent Application Publication
(10) Pub. No.: US 2019/0101580 A1
(43) Pub. Date: Apr. 4, 2019

(54) RADIOFREQUENCY TESTING APPARATUS AND MOVABLE TESTING DEVICE

(71) Applicant: ADIVIC TECHNOLOGY CO.,LTD, TAIPEI CITY (TW)

(72) Inventors: HSIEH-SHENG HUANG, TAIPEI CITY (TW); LI-CHIANG HSING, NEW TAIPEI CITY (TW)

(21) Appl. No.: 15/722,081

(22) Filed: Oct. 2, 2017

(51) Int. Cl. G01R 29/08; H04B 1/10; H04B 1/16; H03H 1/00

(52) U.S. Cl. CPC G01R 29/0878; H03H 1/0007; H04B 1/16; H04B 1/10

(57) ABSTRACT

A movable testing device includes a case module, an aligning box, a lift mechanism connecting the case module and the aligning box, and a flexible shielding member having a tubular shape. The case module has a first accommodating space and a first opening formed on a top portion thereof. The aligning box has a second accommodating space and a second opening formed on a bottom portion thereof. The lift mechanism is configured to rise or fall the aligning box with respect to the case module. The flexible shielding member has a first end portion and an opposite second end portion, which are respectively and seamlessly fastened to the case module and the aligning box and are respectively arranged around the first opening and the second opening. The flexible shielding member defines an adjustable channel in air-communication with the first accommodating space and the second accommodating space.

### BACKGROUND OF THE INVENTION

### 1. Field of the Invention

The present disclosure relates to a testing device; in particular, to a radiofrequency (RF) testing apparatus and a movable testing device.

### 2. Description of Related Art

An object (e.g., an RF chip) needs to be moved into the conventional RF testing apparatus by manpower before the RF testing process is implemented, so that the testing efficiency of the conventional RF testing apparatus needs to be increased. Moreover, in order to get an accurate testing result for the object, the electromagnetic shielding effect of the conventional RF testing apparatus needs to be improved for preventing any external signal from entering into the conventional RF testing apparatus.

### SUMMARY OF THE INVENTION

The present disclosure provides an RF testing apparatus and a movable testing device to effectively improve the drawbacks associated with conventional RF testing apparatuses.

The present disclosure discloses a radiofrequency (RF) testing apparatus, which includes an automatically testing platform and a movable testing device. The automatically testing platform has a testing space and an inserting hole in air-communication with the testing space. The movable testing device includes a case module, an aligning box, a lift mechanism, and an electromagnetic shielding cloth. The case module has a first accommodating space in an interior thereof. A top portion of the case module has a first opening in air-communication with the first accommodating space. The aligning box has a second accommodating space in an interior thereof. A bottom portion of the case module has a second opening in air-communication with the second accommodating space. The lift mechanism connects the case module and the aligning box. The lift mechanism is configured to rise or fall the aligning box with respect to the case module. The electromagnetic shielding cloth is formed as a tubular structure having a first end portion and an opposite second end portion. The first end portion of the electromagnetic shielding cloth is seamlessly fastened to the case module and is arranged around the first opening. The second end portion of the electromagnetic shielding cloth is seamlessly fastened to the aligning box and is arranged around the second opening. An inner space of the electromagnetic shielding cloth is defined as an adjustable channel in air-communication with the first accommodating space and the second accommodating space. The cooperation between the electromagnetic shielding cloth and the case module and the cooperation between the electromagnetic shielding cloth and the aligning box are configured to block an external electromagnetic signal to enter into the first accommodating space and the second accommodating space through the first opening and the second opening. When the movable testing device is moved toward the automatically testing platform to arrange the aligning box under the inserting hole, the lift mechanism is configured to move the aligning box to enter into the testing space through the inserting hole.

The present disclosure also discloses a movable testing device, which includes a case module, an aligning box, a lift mechanism, and a flexible shielding member. The case module has a first accommodating space in an interior thereof. A top portion of the case module has a first opening in air-communication with the first accommodating space. The aligning box has a second accommodating space in an interior thereof. A bottom portion of the case module has a second opening in air-communication with the second accommodating space. The lift mechanism connects the case module and the aligning box. The lift mechanism is configured to rise or fall the aligning box with respect to the case module. The flexible shielding member is formed as a tubular structure having a first end portion and an opposite second end portion. The first end portion of the flexible shielding member is seamlessly fastened to the case module and is arranged around the first opening. The second end portion of the flexible shielding member is seamlessly fastened to the aligning box and is arranged around the second opening. An inner space of the electromagnetic shielding cloth is defined as an adjustable channel in air-communication with the first accommodating space and the second accommodating space.

In summary, the movable testing device of the present disclosure can be moved toward the automatically testing platform to arrange the aligning box under the inserting hole, and the lift mechanism can be operated to move the aligning box to accurately enter into the testing space through the inserting hole, thereby effectively increasing the testing efficiency of the RF testing apparatus.

Moreover, the RF testing apparatus (or the movable testing device) can be used to block an external electromagnetic signal to enter into the first accommodating space and the second accommodating space through the first opening and the second opening by using the cooperation between the electromagnetic shielding cloth and the case module and the cooperation between the electromagnetic shielding cloth and the aligning box.

In order to further appreciate the characteristics and technical contents of the present disclosure, references are hereunder made to the detailed descriptions and appended drawings in connection with the present disclosure. However, the appended drawings are merely shown for exemplary purposes, and should not be construed as restricting the scope of the present disclosure.

### BRIEF DESCRIPTION OF THE DRAWINGS

FIG. 1 is a planar view showing an RF testing apparatus according to the present disclosure;

FIG. 2 is a planar view showing the RF testing apparatus of FIG. 1 when an aligning box is moved into an automatically testing platform;

FIG. 3 is a perspective view showing a movable testing device of FIG. 1;

FIG. 4 is a perspective view showing the movable testing device of FIG. 2;

FIG. 5 is an exploded view showing a part of the movable testing device of FIG. 4 as the internal transmitting cables are omitted; and

FIG. 6 is a cross-sectional view taken along a cross-sectional line VI-VI of FIG. 4 as the internal transmitting cables are omitted.

### DETAILED DESCRIPTION OF THE PREFERRED EMBODIMENTS

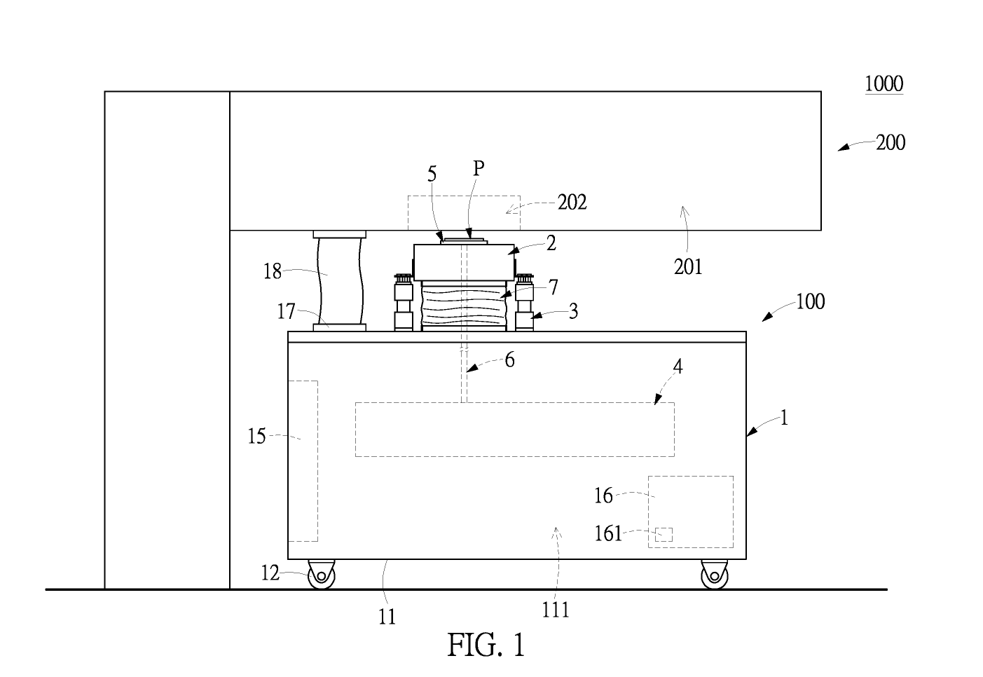

Reference is made to FIGS. 1 to 6, which illustrate the present disclosure. References are hereunder made to the detailed descriptions and appended drawings in connection with the present disclosure. However, the appended drawings are merely provided for exemplary purposes, and should not be construed as restricting the scope of the present disclosure.

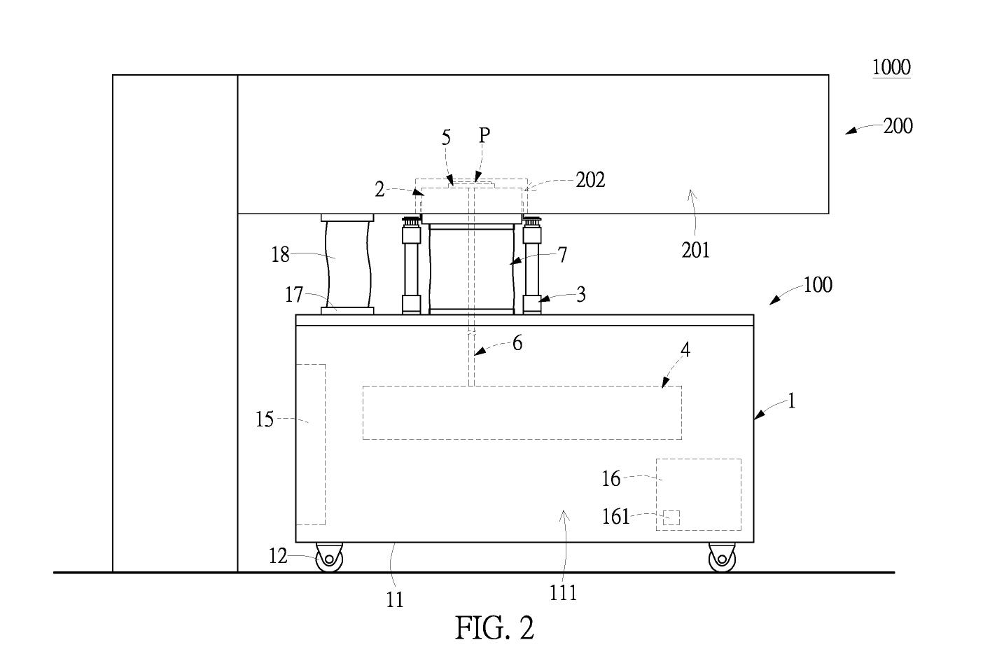

Reference is first made to FIGS. 1 and 2, which illustrate a radiofrequency (RF) testing apparatus 1000 of the present disclosure. The RF testing apparatus 1000 includes an automatically testing platform 200 and a movable testing device 100 cooperated with the automatically testing platform 200. The automatically testing platform 200 has a testing space 201 and an inserting hole 202 in air-communication with the testing space 201. The movable testing device 100 can move an object (i.e., an RF chip) to enter into the testing space 201 through the inserting hole 202 for implementing an RF test to the object.

It should be noted that the movable testing device 100 in the present embodiment is cooperated with the automatically testing platform 200, but the movable testing device 100 in the present disclosure is not limited thereto.

As shown in FIGS. 1 to 6, the movable testing device 100 includes a case module 1, an aligning box 2, a lift mechanism 3, an RF analytical instrument 4, a socket connector 5, a plurality of internal transmitting cables 6, and a flexible shielding member 7. The flexible shielding member 7 in the present embodiment is an electromagnetic shielding cloth 7, but the present disclosure is not limited thereto. That is to say, the flexible shielding member 7 in the present disclosure is preferably provided with a flexible and electromagnetic shielding function. The following description discloses the structure and connection of each component of the movable testing device 100.

As shown in FIGS. 2, 4, and 6, the case module 1 in the present embodiment includes a case 11, a plurality of rollers 12, a first conductive foam 13, a first holder 14, a honeycomb electromagnetic shielding structure 15, a power supply 16, an external connector 17, and an external transmitting cable 18. The following description discloses the structure and connection of each component of the case module 1.

The case 11 in the present embodiment is substantially a cuboid and is made of a metallic material, but the present disclosure is not limited thereto. The case 11 has a first accommodating space 111 in an interior thereof, at least one heat dissipating hole 112 formed on a side surface thereof, and a first opening 113 formed on a top portion thereof and in air-communication with the first accommodating space 111.

Specifically, the case 11 has a first ridge 114 arranged outside the first accommodating space 111 and arranged around the first opening 113. That is to say, the shape of the first ridge 114 is preferably formed according to the shape of the first opening 113. In the present embodiment, the first opening 113 has a rectangular (or square) shape, and the first ridge 114 has a rectangular (or square) annular shape, but the present disclosure is not limited thereto.

The rollers 12 are mounted on a bottom portion of the case 11, so that the movable testing device 100 can be moved to any position by using the rollers 12. Thus, the movable testing device 100 can be moved toward the automatically testing platform 200 to arrange the aligning box 2 under the inserting hole 202, and the lift mechanism 3 is configured to move the aligning box 3 to accurately enter into the testing space 201 through the inserting hole 202.

The first conductive foam 13 and the first holder 14 are fastened to the first ridge 114. That is to say, the first conductive foam 13 and the first holder 14 are corresponding in shape to the first ridge 114, and each of the first conductive foam 13 and the first holder 14 is arranged around the first ridge 114. In the present embodiment, the first conductive foam 13 includes a plurality of foam stripes arranged around the first ridge 114, and the first holder 14 includes a plurality of elongated sheets arranged around the foam stripes, but the present disclosure is not limited thereto. For example, in other embodiments of the present disclosure, the first holder 14 can be two L-shaped sheets.

The honeycomb electromagnetic shielding structure 15 is wedged in the heat dissipating hole 112 of the case 11 for blocking an electromagnetic signal. That is to say, any external electromagnetic signal needs to travel through the honeycomb electromagnetic shielding structure 15 before passing through the heat dissipating hole 112. Thus, the honeycomb electromagnetic shielding structure 15 is configured to block any external electromagnetic signal to enter into the first accommodating space 111 through the heat dissipating hole 112.

It should be noted that the case module 1 in the present embodiment is provided with one honeycomb electromagnetic shielding structure 15 wedged in one heat dissipating hole 112, but the present disclosure is not limited thereto. For example, in other embodiments of the present disclosure, the case 11 can be formed with a plurality of heat dissipating holes 112, and the case module 1 includes a plurality of honeycomb electromagnetic shielding structures 15 respectively wedged in the heat dissipating holes 112, so that air convention can be formed in the first accommodating space 111 of the case 11 by the honeycomb electromagnetic shielding structures 15. Moreover, each of the honeycomb electromagnetic shielding structures 15 can be provided with a fan for enhancing air convention.

The power supply 16 is installed on the case 11 for connecting to an external alternating current (AC) outlet (e.g., a mains outlet), so that the movable testing device 100 can be operated by acquiring electricity from the external AC outlet. Moreover, the power supply 16 has an AC filter 161, and the AC filter 161 is configured to block an external electromagnetic signal to enter into the first accommodating space 111 through the power supply 16.

The external connector 17 is installed on a top portion of the case 11. Two opposite ends of the external transmitting cable 18 are respectively connected to the external connector 17 and the automatically testing platform 200 so as to establish an electrical connection between the movable testing device 100 and the automatically testing platform 200. The external connector 17 is configured to block an external electromagnetic signal to enter into the first accommodating space 111.

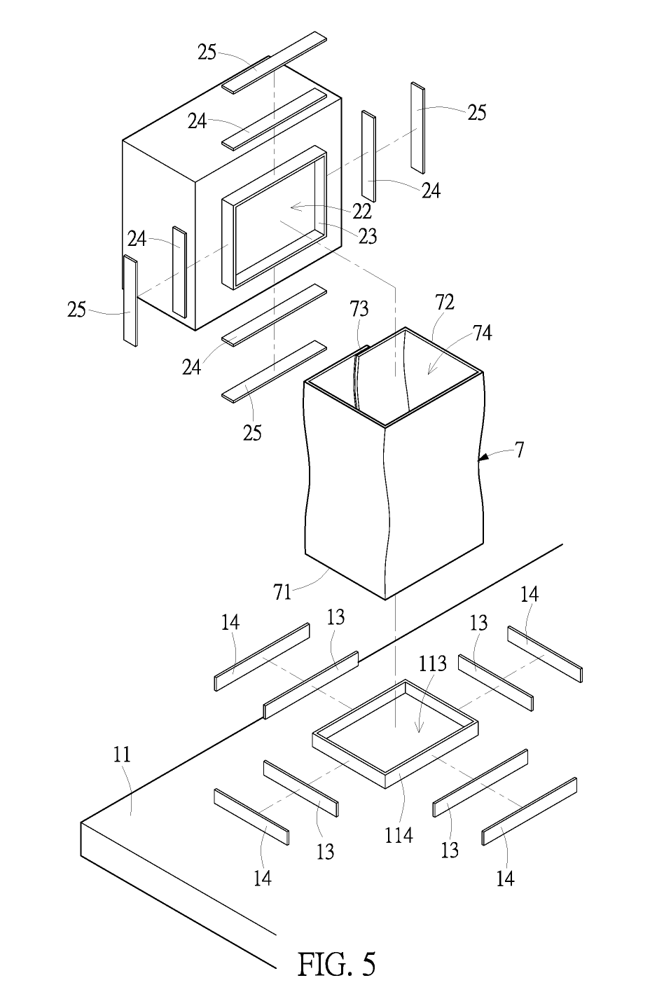

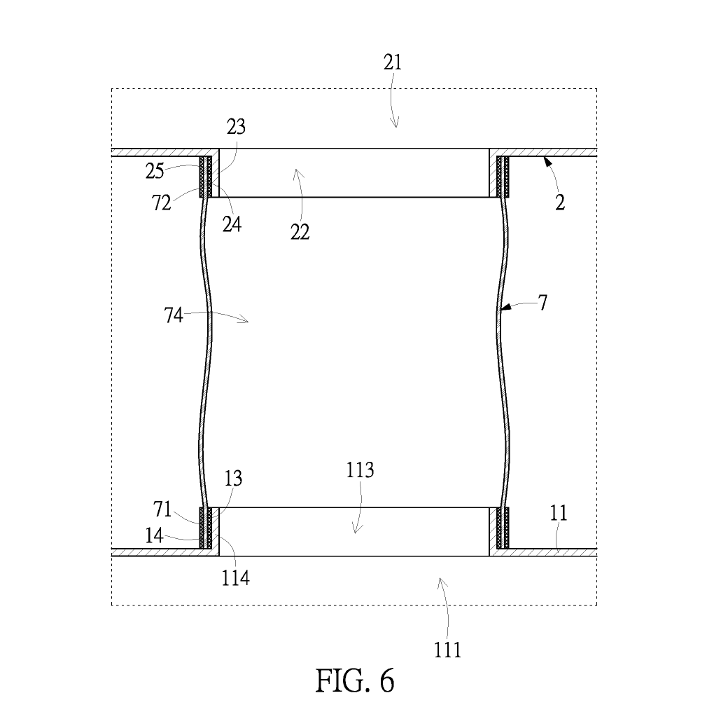

As shown in FIGS. 5 and 6, the aligning box 2 in the present embodiment is substantially a cuboid and is made of a metallic material, but the present disclosure is not limited thereto. The size of the aligning box 2 is smaller than that of the case 11, and the aligning box 2 has a second accommodating space 21 in an interior thereof. The bottom portion of the aligning box 2 has a second opening 22 in air-communication with the second accommodating space 21.

The aligning box 2 includes a second ridge 23, a second conductive foam 24, and a second holder 25. The second ridge 23 is arranged outside the second accommodating space 21 and is arranged around the second opening 22. That is to say, the shape of the second ridge 23 is preferably formed according to the shape of the second opening 22. In the present embodiment, the second opening 22 has a rectangular (or square) shape, and the second ridge 23 has a rectangular (or square) annular shape, but the present disclosure is not limited thereto.

The second conductive foam 24 and the second holder 25 are fastened to the second ridge 23. That is to say, the second conductive foam 24 and the second holder 25 are corresponding in shape to the second ridge 23, and each of the second conductive foam 24 and the second holder 25 is arranged around the second ridge 23. In the present embodiment, the second conductive foam 24 includes a plurality of foam stripes arranged around the second ridge 23, and the second holder 25 includes a plurality of elongated sheets arranged around the foam stripes, but the present disclosure is not limited thereto. For example, in other embodiments of the present disclosure, the second holder 25 can be two L-shaped sheets.

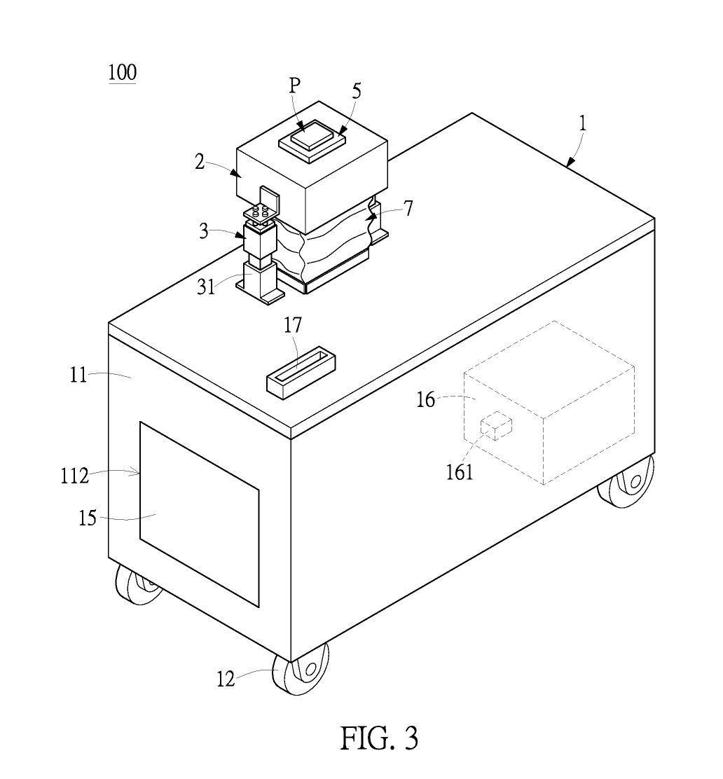

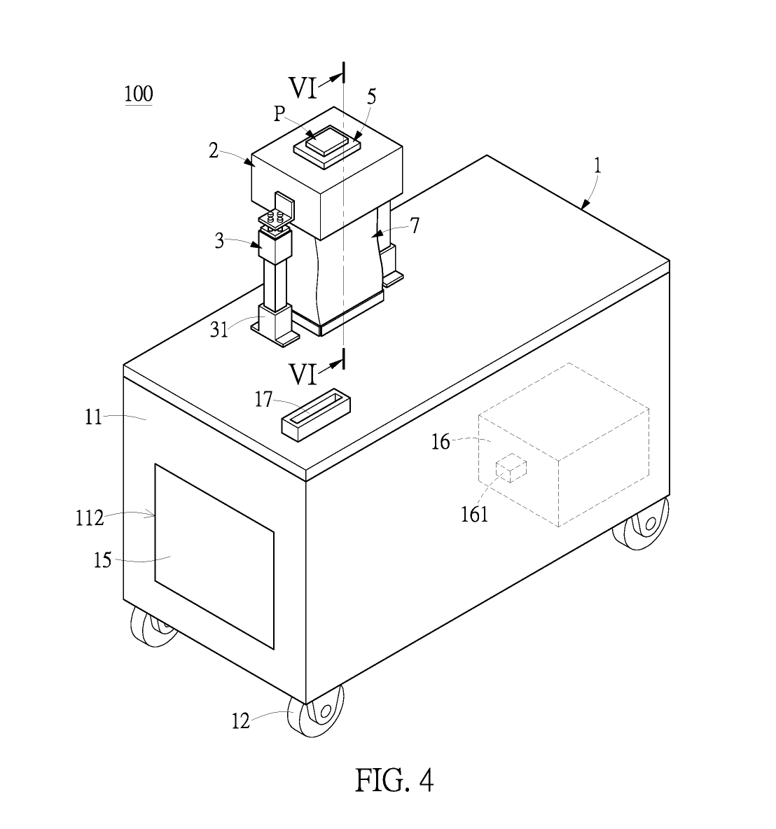

As shown in FIGS. 3 and 4, the lift mechanism 3 connects the case module 1 and the aligning box 2, and the lift mechanism 3 is configured to rise or fall the aligning box 2 with respect to the case module 1. The lift mechanism 3 in the present embodiment includes two pneumatic cylinders 31, the bottom portions of the two pneumatic cylinders 31 are fixed on the top portion of the case 11 and are respectively arranged at two opposite sides of the first opening 113, and the top portions of the two pneumatic cylinders 31 are fixed on two opposite side surfaces of the aligning box 2. Thus, the two pneumatic cylinders 31 can be operated to rise or fall the aligning box 2 with respect to the case module 1, but the present disclosure is not limited thereto.

As shown in FIGS. 1 and 2, the RF analytical instrument 4 is arranged in the first accommodating space 111 of the case module 1, and the RF analytical instrument 4 is electrically connected to the external connector 17 which is disposed on the top portion of the case 11, by using at least one cable (not shown). Moreover, two opposite ends of the external transmitting cable 18 are respectively connected to the external connector 17 and the automatically testing platform 200 so as to establish an electrical connection between the RF analytical instrument 4 and the automatically testing platform 200.

As shown in FIGS. 2, 4, and 6, the socket connector 5 is installed on the top portion of the aligning box 2 for providing an insertion and an electrical connection to an object (e.g., an RF chip). The internal transmitting cables 6 are arranged in the first accommodating space 111, a space (i.e., an adjustable channel 74 as disclosed in the following descriptions) between the first opening 113 and the second opening 23, and the second accommodating space 21. One end of each of the internal transmitting cables 6 is connected to the socket connector 5 and the other end of each of the internal transmitting cables 6 is connected to the RF analytical instrument 4, thereby electrically connecting the socket connector 5 (and the object inserted into the socket connector 5) to the RF analytical instrument 4. Thus, when the object is arranged in and is tested by the automatically testing platform 200, the RF analytical instrument 4 can be used to analyze the testing data of the object by electrically connecting the object to the automatically testing platform 200.

As shown in FIGS. 3 to 6, the electromagnetic shielding cloth 7 is substantially formed as a tubular structure having a first end portion 71 (i.e., the bottom portion of the electromagnetic shielding cloth 7 as shown in FIG. 5) and an opposite second end portion 72 (i.e., the top portion of the electromagnetic shielding cloth 7 as shown in FIG. 5). In the present embodiment, two sides of the electromagnetic shielding cloth 7 are seamlessly connected by a double-sided conductive adhesive 73 to form the tubular structure, so that the adhering portions of the electromagnetic shielding cloth 7 have an electromagnetic shielding function by the double-sided conductive adhesive 73, but the present disclosure is not limited thereto.

Specifically, the first end portion 71 of the electromagnetic shielding cloth 7 is seamlessly fastened to the case module 1 and is arranged around the first opening 113, the second end portion 72 of the electromagnetic shielding cloth 7 is seamlessly fastened to the aligning box 2 and is arranged around the second opening 22, and an inner space of the electromagnetic shielding cloth 7 is defined as an adjustable channel 74 in air-communication with the first accommodating space 111 and the second accommodating space 21. Thus, the cooperation between the electromagnetic shielding cloth 7 and the case module 1 and the cooperation between the electromagnetic shielding cloth 7 and the aligning box 2 are configured to block an external electromagnetic signal to enter into the first accommodating space 111 and the second accommodating space 21 through the first opening 113 and the second opening 22.

It should be noted that the electromagnetic shielding cloth 7 in the present embodiment has a specific stiffness and is not a soft structure. In order to have a better shielding effect on the cooperation between the electromagnetic shielding cloth 7 and the case module 1, the electromagnetic shielding cloth 7 and the case 11 of the case module 1 are preferably provided with a soft conductive material arranged there-between for achieving a seamless connection between the electromagnetic shielding cloth 7 and the case 11.

Specifically, the first end portion 71 of the electromagnetic shielding cloth 7 and the first conductive foam 13 are sandwiched between the first holder 14 and the first ridge 114 so as to substantially establish a seamless connection between the first end portion 71 of the electromagnetic shielding cloth 7 and the first conductive foam 13. The second end portion 72 of the electromagnetic shielding cloth 7 and the second conductive foam 24 are sandwiched between the second holder 25 and the second ridge 23 so as to substantially establish a seamless connection between the second end portion 72 of the electromagnetic shielding cloth 7 and the second conductive foam 24.

In the present embodiment, the first conductive foam 13 is sandwiched between the first end portion 71 and the first ridge 114, and the second conductive foam 24 is sandwiched between the second end portion 72 and the second ridge 23, but the present disclosure is not limited thereto. For example, in other embodiments of the present disclosure, the first conductive foam 13 can be sandwiched between the first end portion 71 and the first holder 14, and the second conductive foam 24 is sandwiched between the second end portion 72 and the second holder 25.

Thus, the honeycomb electromagnetic shielding structure 15, the power supply 16 having the AC filter 161, the external connector 17, the cooperation between the electromagnetic shielding cloth 7 and the case module 1, and the cooperation between the electromagnetic shielding cloth 7 and the aligning box 2 are configured to (entirely) block any external electromagnetic signal to enter into the first accommodating space 111, the adjustable channel 74, and the second accommodating space 21.

### The Effects of the Present Embodiment

In summary, the movable testing device 100 of the present disclosure can be moved toward the automatically testing platform 200 to arrange the aligning box 2 under the inserting hole 202, and the lift mechanism 3 can be operated to move the aligning box 3 to accurately enter into the testing space 201 through the inserting hole 202, thereby effectively increasing the testing efficiency of the RF testing apparatus 1000. In the RF testing apparatus 1000 (or the movable testing device 100), the cooperation between the electromagnetic shielding cloth 7 and the case module 1 and the cooperation between the electromagnetic shielding cloth 7 and the aligning box 2 are configured to block an external electromagnetic signal to enter into the first accommodating space 111 and the second accommodating space 21 through the first opening 113 and the second opening 22, thereby preventing the external electromagnetic signal from interfering with the testing process of the movable testing device 100.

Moreover, the electromagnetic shielding cloth 7 in the present disclosure has a specific stiffness and is not a soft structure, so that the first end portion 71 and the second end portion 72 of the electromagnetic shielding cloth 7 are preferably abutted against a soft conductive material to substantially establish a seamless connection there-between. For example, the first end portion 71 of the electromagnetic shielding cloth 7 and the first conductive foam 13 are sandwiched between the first holder 14 and the first ridge 114, and the second end portion 72 of the electromagnetic shielding cloth 7 and the second conductive foam 24 are sandwiched between the second holder 25 and the second ridge 23, thereby achieving a better shielding effect.

In addition, in order to (entirely) block any external electromagnetic signal to enter into the first accommodating space 111, the adjustable channel 74, and the second accommodating space 21, the movable testing device 100 further includes the honeycomb electromagnetic shielding structure 15, the power supply 16 having the AC filter 161, and the external connector 17.

The descriptions illustrated supra set forth simply the preferred embodiments of the present disclosure; however, the characteristics of the present disclosure are by no means restricted thereto. All changes, alterations, or modifications conveniently considered by those skilled in the art are deemed to be encompassed within the scope of the present disclosure delineated by the following claims.

What is claimed is:

1. A radiofrequency (RF) testing apparatus, comprising:
an automatically testing platform having a testing space and an inserting hole in air-communication with the testing space; and
a movable testing device including:
a case module having a first accommodating space in an interior thereof, wherein a top portion of the case module has a first opening in air-communication with the first accommodating space;
an aligning box having a second accommodating space in an interior thereof, wherein a bottom portion of the case module has a second opening in air-communication with the second accommodating space;
a lift mechanism connecting the case module and the aligning box, wherein the lift mechanism is configured to rise or fall the aligning box with respect to the case module;
an electromagnetic shielding cloth formed as a tubular structure having a first end portion and an opposite second end portion, wherein the first end portion of the electromagnetic shielding cloth is seamlessly fastened to the case module and is arranged around the first opening, the second end portion of the electromagnetic shielding cloth is seamlessly fastened to the aligning box and is arranged around the second opening, and an inner space of the electromagnetic shielding cloth is defined as an adjustable channel in air-communication with the first accommodating space and the second accommodating space, wherein the cooperation between the electromagnetic shielding cloth and the case module and the cooperation between the electromagnetic shielding cloth and the aligning box are configured to block an external electromagnetic signal to enter into the first accommodating space and the second accommodating space through the first opening and the second opening,
wherein when the movable testing device is moved toward the automatically testing platform to arrange the aligning box under the inserting hole, the lift mechanism is configured to move the aligning box to enter into the testing space through the inserting hole.

2. The RF testing apparatus as claimed in claim 1, wherein the movable testing device includes:
an RF analytical instrument arranged in the first accommodating space of the case module;
a socket connector installed on a top portion of the aligning box for providing an insertion and an electrical connection to an object; and
a plurality of internal transmitting cables arranged in the first accommodating space, the adjustable channel, and the second accommodating space, wherein one end of each of the internal transmitting cables is connected to the socket connector, and the other end of each of the internal transmitting cables is connected to the RF analytical instrument.

3. The RF testing apparatus as claimed in claim 2, wherein the case module includes:
a case surroundingly defining the first accommodating space, wherein the case has a heat dissipating hole in air-communication with the first accommodating space;
a honeycomb electromagnetic shielding structure wedged in the heat dissipating hole of the case;
a power supply for connecting to an external alternating current (AC) outlet, wherein the power supply is installed on the case and has an AC filter;
an external connector installed on the case and electrically connected to the RF analytical instrument; and
an external transmitting cable having two opposite ends respectively connected to the external connector and the automatically testing platform so as to establish an electrical connection between the RF analytical instrument and the automatically testing platform,
wherein the honeycomb electromagnetic shielding structure, the power supply, the external connector, the cooperation between the electromagnetic shielding cloth and the case module, and the cooperation between the electromagnetic shielding cloth and the aligning box are configured to block the external electromagnetic signal to enter into the first accommodating space, the adjustable channel, and the second accommodating space.

4. The RF testing apparatus as claimed in claim 1, wherein two sides of the electromagnetic shielding cloth are seamlessly connected by a double-sided conductive adhesive to form the tubular structure; the case module includes a case, a first conductive foam, and a first holder, wherein the case has a first ridge arranged outside the first accommodating space and arranged around the first opening, and the first conductive foam and the first holder are fastened to the first ridge; the aligning box includes a second ridge, a second conductive foam, and a second holder, wherein the second ridge is arranged outside the second accommodating space and is arranged around the second opening, and the second conductive foam and the second holder are fastened to the second ridge; the first end portion and the first conductive foam are sandwiched between the first holder and the first ridge so as to substantially establish a seamless connection between the first end portion and the first conductive foam, and the second end portion and the second conductive foam are sandwiched between the second holder and the second ridge so as to substantially establish a seamless connection between the second end portion and the second conductive foam.

5. A movable testing device, comprising:
a case module having a first accommodating space in an interior thereof, wherein a top portion of the case module has a first opening in air-communication with the first accommodating space;
an aligning box having a second accommodating space in an interior thereof, wherein a bottom portion of the case module has a second opening in air-communication with the second accommodating space;
a lift mechanism connecting the case module and the aligning box, wherein the lift mechanism is configured to rise or fall the aligning box with respect to the case module;
a flexible shielding member formed as a tubular structure having a first end portion and an opposite second end portion, wherein the first end portion of the flexible shielding member is seamlessly fastened to the case module and is arranged around the first opening, the second end portion of the flexible shielding member is seamlessly fastened to the aligning box and is arranged around the second opening, and an inner space of the electromagnetic shielding cloth is defined as an adjustable channel in air-communication with the first accommodating space and the second accommodating space.

6. The movable testing device as claimed in claim 5, wherein the case module includes a case and a honeycomb electromagnetic shielding structure, the case surroundingly defines the first accommodating space and has a heat dissipating hole in air-communication with the first accommodating space, and the honeycomb electromagnetic shielding structure is wedged in the heat dissipating hole of the case.

7. The movable testing device as claimed in claim 6, wherein the case module includes a power supply and an external connector, the power supply has an AC filter and is installed on the case for connecting to an external AC outlet, and the external connector is installed on the case.

8. The movable testing device as claimed in claim 5, wherein the case module includes a case, a first conductive foam, and a first holder, wherein the case has a first ridge arranged outside the first accommodating space and arranged around the first opening, and the first conductive foam and the first holder are fastened to the first ridge; the aligning box includes a second ridge, a second conductive foam, and a second holder, wherein the second ridge is arranged outside the second accommodating space and is arranged around the second opening, and the second conductive foam and the second holder are fastened to the second ridge; the first end portion and the first conductive foam are sandwiched between the first holder and the first ridge so as to substantially establish a seamless connection between the first end portion and the first conductive foam, and the second end portion and the second conductive foam are sandwiched between the second holder and the second ridge so as to substantially establish a seamless connection between the second end portion and the second conductive foam.

9. The movable testing device as claimed in claim 5, wherein the flexible shielding member is limited to an electromagnetic shielding cloth, and two sides of the electromagnetic shielding cloth are seamlessly connected by a double-sided conductive adhesive to form the tubular structure, wherein the cooperation between the electromagnetic shielding cloth and the case module and the cooperation between the electromagnetic shielding cloth and the aligning box are configured to block an external electromagnetic signal to enter into the first accommodating space and the second accommodating space through the first opening and the second opening.

10. The movable testing device as claimed in claim 5, further comprising:
an RF analytical instrument arranged in the first accommodating space of the case module;
a socket connector installed on a top portion of the aligning box for providing an insertion and an electrical connection to an object; and
a plurality of internal transmitting cables arranged in the first accommodating space, the adjustable channel, and the second accommodating space, wherein one end of each of the internal transmitting cables is connected to the socket connector, and the other end of each of the internal transmitting cables is connected to the RF analytical instrument.
